(19) United States
(12) Patent Application Publication
(10) Pub. No.: US 2007/0264428 A1
(43) Pub. Date: Nov. 15, 2007

(54) Corrosion Preventing Method

(75) Inventor: Hagane Irikura, Ibaraki (JP)

Correspondence Address: KRATZ, QUINTOS & HANSON, LLP, 1420 K Street, N.W., Suite 400, WASHINGTON, DC, 20005, US

(73) Assignee: ULVAC, INC., Kanagawa (JP)

(21) Appl. No.: 11/629,748

(22) PCT Filed: Nov. 10, 2005
(86) PCT No.: PCT/JP05/20571

§ 371 Date: May 22, 2007

(30) Foreign Application Priority Data
Nov. 22, 2004 (JP) 2004-338188

(51) Int. Cl. C23C 16/00

(52) U.S. Cl. 427/255.28

(57) ABSTRACT

For putting the application of an Ni—Ti alloy to a biomaterial into practical use, a corrosion preventing method combined with biocompatibility is provided. It is a corrosion preventing method for a metal substrate used for biomaterials in which a polyimide coating layer is formed on the metal substrate by vapor deposition polymerization.

### TECHNICAL FIELD

The present invention concerns a corrosion preventing method for biomaterials applied to guide wires, catheters, stents, etc. used for inspection or treatment apparatus as medical equipments, as well as orthodontic wires, implants, etc., as dental equipments.

### BACKGROUND ART

In recent years, application of utilizing the function of shape memory alloys typically represented by Ni—Ti alloy utilized for medical instruments has attracted attention. The range of the application use of the Ni—Ti alloys in the medical field has now been extended to guide wires, catheters, stents, etc. Further, the application use to implants as the dental instruments has also attracted attention.

Metals used as medical instruments including the metals described above including those of dental use are inevitably required to be corrosion proof and biocompatible since they are inserted or attached to the biobody.

As a method of providing the corrosion proofness to a substrate material, Non-Patent Document 1 discloses a corrosion preventing method of spraying Ti to an Ni—Ti alloy substrate and coating the sprayed Ti layer with a polymeric material.

The document discloses that a silicon resin, a two-component epoxy resin, or a cyano acrylic resin dissolved in a solvent such as carbon tetrachloride or acetone, or a molten amide resin is impregnated into the Ti grain boundary for sealing since Ni—Ti as a substrate suffers from pitting corrosion by physiological saline through Ti grain boundary in a case where Ti is merely plasma sprayed to the substrate.

However, those disclosed therein do not satisfy both the corrosion proofness and the biocompatibility, and as for pitting corrosion those have a ploblem of Ni leaching in particular.

Further, for those aiming at corrosion prevention, Patent Document 1 discloses spraying Ti to an Ni—Ti substrate and a polymeric resin is coated with the Ti layer.

However, it was difficult to prevent the material such as a solvent which is toxic to living bodies from remaining in the substrate (sprayed with Ti), in the existent method of coating the polymeric resin in a wet system of impregnation as disclosed in the Patent Document 1.

Non-Patent Document 1: J. Technology and Education, Vol. 11, No. 1, pp. 1-8, 2004

Patent Document 1: JP-A No. 2003-193216

### DISCLOSURE OF THE INVENTION

Subject to be Solved by the Invention

In order to overcome the problems in the prior art described above and put the application of the Ni—Ti alloy for the application use of biomaterial into practical use, the present invention has a subject of finding a corrosion preventing method also providing biocompatibility.

Means for Solving the Subject

As a result of an earnest study for solving the subject described above, the present inventors have found that even in a case where a pore portion, for example, is formed on the surface of a sprayed metal layer formed for corrosion prevention on the surface of the metal substrate, a polyimide coating layer is formed by vapor deposition polymerization also to the surface in the deep pore portion, and the thus formed polyimide coating layer has both corrosion proofness and biocompatibility.

The present invention has been achieve based on such finding and the corrosion preventing method of the invention has a feature, in a corrosion protecting method of a metal substrate used for a biomaterial as described in claim 1 in that a polyimide coating film is formed by vapor deposition polymerization to the metal substrate.

Further, a corrosion preventing method described in claim 2 is a corrosion preventing method according to claim 1, wherein the sprayed metal layer is formed on the surface of the metal substrate and then a polyimide coating layer is formed by vapor deposition polymerization.

Further, a corrosion preventing method described in claim 3 is a corrosion preventing method according to claim 1, wherein the metal substrate is a shape memory alloy.

Further, a corrosion preventing method described in claim 4 is a corrosion preventing method according to claim 2, wherein the sprayed metal layer comprises Ti.

Further, a corrosion preventing method described in claim 5 is a corrosion preventing method according to claim 2, wherein the metal substrate is a shape memory alloy and the sprayed metal layer comprises Ti.

Further, the biomaterial of the invention is characterized to be produced by a corrosion preventing method according to claim 1 as described in claim 6.

Further, the biomaterial of the invention is characterized to be prepared by a corrosion preventing method according to claim 4 as described in claim 7.

Effect of the Invention

According to the present invention, by forming the polyimide coating layer by vapor deposition polymerization on Ni—Ti shape memory alloys, etc. which are utilized for application use of biomaterials, it becomes possible to provide a metal substrate such as Ni—Ti shape memory alloys with corrosion proofness in a living body as well as biocompatibility.

### BRIEF DESCRIPTION OF THE DRAWINGS

FIG. 1 is a schematic view of vapor deposition polymerization apparatus for practicing a corrosion preventing method of the present invention.

FIG. 2 is a graph showing the result of a polarization test by an electrostatic potential sweeping method in physiological saline for evaluation of corrosion prevention.

FIG. 3 is a graph showing a toxicity evaluation test using ciliata living in the soils of rivers for confirming the biocompatibility.

### DESCRIPTION OF REFERENCE NUMERALS AND SIGNS

1 vapor deposition polymerization apparatus
2 evacuating system
3 processing chamber
4 holding jig
5 heater
6 heating vessel
7 monomer gas introduction port
10 metal substrate

### BEST MODE FOR CARRYING OUT THE INVENTION

The corrosion preventing method according to the present invention is a corrosion preventing method for metal substrates used for biomaterials in which a polyimide coating layer is formed by vapor deposition polymerization on a metal substrate. For example, a starting monomer gas is introduced in a processing chamber such as a vacuum vessel under a state that the metal substrate is heated to a predetermined temperature, to conduct polymerizing reaction on the entire surface of the metal substrate and form a polyimide coating layer.

The metal substrate includes Ni—Ti shape memory alloys, as well as Ni—Ti based shape memory alloys with addition of several % or less of Cr, Fe, V, Co, etc., and Ni—Ti—Nb-based, Cu—Zn—Al-based, or Fe—Mn—Si-based shape memory alloys. The metal substrate is not restricted to the shape memory alloys but may also be stainless steel, aluminum, aluminum alloy, iron, copper, or noble metals such as gold or silver.

Further, the polyimide coating layer by the vapor deposition polymerization may be formed directly to the surface of the metal substrate and it may also be formed to the sprayed metal layer formed on for corrosion prevention the surface of the metal substrate. While pores are formed in a case of forming the sprayed metal layer as described above, since the polyimide coating film is formed by vapor deposition polymerization also on the surface of the deep portion of the pores, the surface of the pore portion in communication with the substrate is kept in a favorable state even when the uppermost surface layer is abraded. Accordingly, particularly excellent corrosion proofness and biocompatibility can be attained.

The vapor deposition polymerization of the polyimide coating layer is not particularly different from existent vapor deposition polymerization of polyimide regarding the starting monomer, vapor deposition condition, etc. and, for example, a combination of pyromellitic acid anhydride (PMDA) and 4,4′-oxydianiline (ODA) or a combination of PMDA and 3,5′-diaminobenzoic acid (DBA) may be used with no particular restriction.

Further, the polyimide coating layer to be formed is applicable within a range of thickness of 1 μm or more. This is because the corrosion preventive performance is insufficient when it is less than 1 μm. Further, in view of the industrial use, it is preferably within a range from 1 to 10 μm in view of the cost.

Further, in a case of forming the sprayed Ti layer, the sprayed Ti layer is applicable within a range of thickness from 1 to 300 μm. This is because the corrosion preventive performance is insufficient in a case where it is less than 1 μm and, on the contrary, corrosion of the substrate is rather promoted when it exceeds 300 μm.

### EXAMPLE

Then, an example of the present invention is to be described.

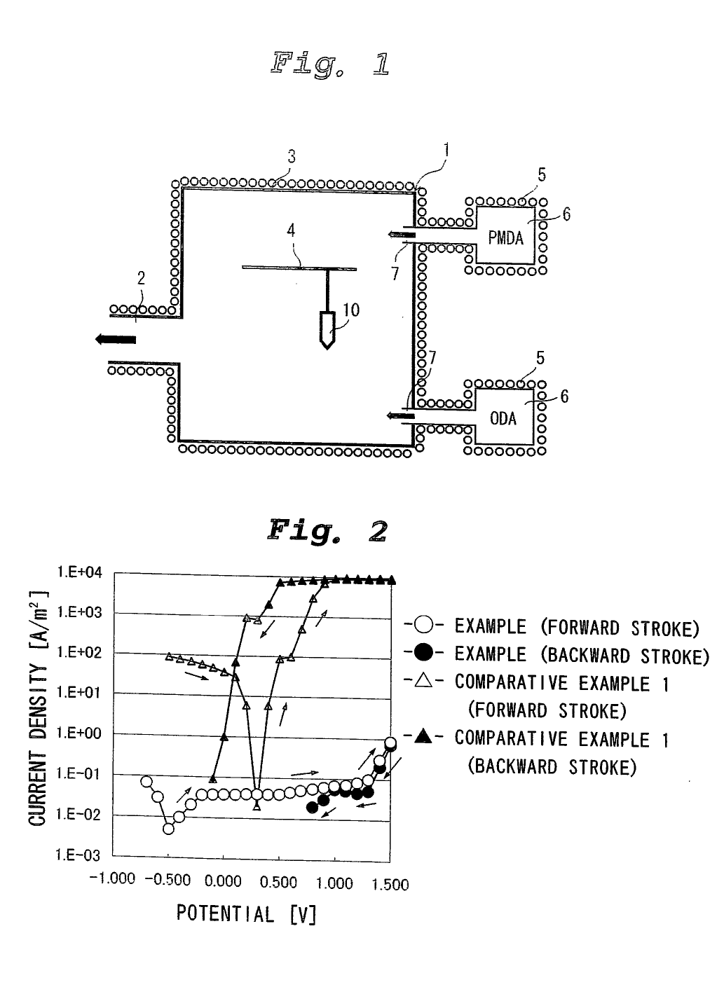

FIG. 1 shows a vapor deposition polymerization apparatus used in this example. In the vapor deposition polymerization apparatus depicted by 1 in the drawing, a metal substrate 10 to be applied with a corrosion prevention treatment is held by a holding jig 4 in a processing chamber 3 in communication with an evacuating system 2, monomer gas introduction ports 7 of two heating vessels 6 each of which can be heated to a predetermined temperature by a heater 5 disposed at the outer periphery are in communication with the processing chamber 3. Pyromellitic acid anhydride (PMDA) is contained in one heating vessel 6 and 4,4′-oxydianiline (ODA) is contained in the other heating vessel 6, and a gas of pyromellitic acid anhydride (PMDA) vapors and a gas of 4,4′-oxydianiline (ODA) vapors are introduced in the processing chamber 3 so that the polyimide coating layer can be formed on the surface of the metal substrate 10 by making those gases react.

Then, an example of the corrosion preventing method using the vapor deposition polymerization apparatus described above is to be described specifically.

As an object to be subjected to a corrosion preventive treatment, a metal substrate 10 of a bar-shape of 3 mm in diameter and 50 mm in length formed into a conical shape at one end and comprising an Ni—Ti alloy of 50 at.% Ni content was used.

After applying a blast treatment to the surface of the metal substrate 10, Ti particles with a grain size of 5 to 20 μm were plasma sprayed to form a sprayed Ti layer of 120 μm thickness. The blasting treatment was conducted with an aim of improving the adhesion between the metal substrate 10 and the sprayed Ti layer.

Then, the metal substrate 10 having the sprayed Ti layer formed thereon was held by the holding jig 4 in the processing chamber 3, the inside of the processing chamber 3 was evacuated to 1×10⁻² Pa or lower, and then the metal substrate 10 was heated by a heater not illustrated in the drawing to a temperature of 200° C. Gas of pyromellitic acid anhydride (PMDA) vapor was introduced from the heating vessel 6 heated to 210° C. by the heater 5, and a gas of 4,4′-oxydianiline (ODA) vapor was introduced from the heating vessel 6 heated to 190° C. by the heater 5 by way of monomer gas introduction ports 7, 7 and vapor deposition polymerization reaction was taken place on the surface of the metal substrate 10 at a film forming pressure of 10 Pa for 12 min to form a polyimide layer of 2 μm thickness on the sprayed Ti layer. Then, it was heated at 300° C. to stabilize the imide.

When the cross section of the thus prepared sample was observed under an electron microscope, it was confirmed that the Ti particle surface was coated with the polyimide coating layer at the Ti grain boundary on the surface of the sprayed Ti layer.

While the film forming pressure was set to 10 Pa in the example described above, the formation of the polyimide coating can be conducted at a film forming pressure within a range from 1 to 100 Pa.

Then, for evaluation of corrosion prevention of the example, a polarization test was conducted by an electrostatic potential sweep method in physiological saline.

The polarization proceeded at first in the direction of the anode from the electrostatic potential less noble by 0.35 V than the immersion electrostatic potential, the polarizing direction is reversed when the current increased to reach about three digits and polarization was conducted to an electrostatic potential where the current was reduced to zero (passivation electrostatic potential). The electrostatic potential sweeping speed was set to 2.1 mV/sec. Pt was used for the counter electrode and Ag—AgCl was used for the reference electrode. The liquid temperature was kept at 40° C. and pure nitrogen gas was used for deaeration.

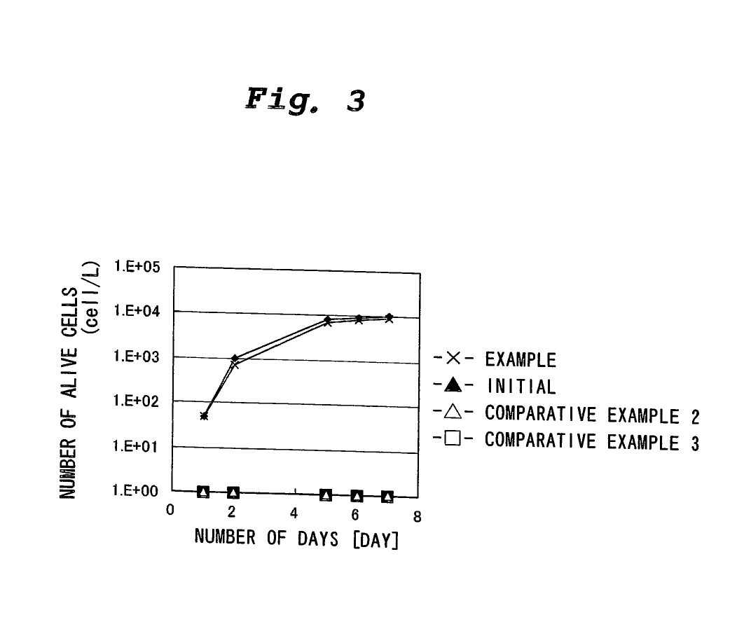

FIG. 2 shows the result of the polarization test. In the drawing, blank circles show the forward stroke of the electrostatic potential sweeping and solid circles show the backward stroke of the electrostatic potential sweeping. In view of FIG. 2, in the example in which the polyimide coating layer is formed it can be seen that hysteresis due to the polarization reversion is not found and pitting corrosion of the substrate that means leaching of Ni is prevented.

### Comparative Example 1

Further, for comparison with the example, a sample only formed with the sprayed Ti layer identical with the example was prepared and the result of the polarization test conducted in the same manner is shown in FIG. 2. In the drawing, blank triangles show the forward stroke of the electrostatic potential sweeping, while solid triangles show the backward stroke of the electrostatic potential sweeping. In FIG. 2, in the Comparative Example 1, it can be seen that hysteresis is caused due to the reversion of polarization and it can be seen that pitting corrosion was formed in the substrate.

Then, for confirming the biocompatibility of the sample, a toxicity evaluation test using ciliata living in the soils of rivers (“Environmental Microorganism Experimental Method”, by Ryuichi Sudo, from Kodansha (Japan), p 86).

The medium used was Cereal Leaves (Sigma) medium which was a liquid filtrate obtained by boiling 0.2% Cereal Leaves for 5 min. A sample was put in a 50 ml Erlenmeyer flask and dipped in 30 ml of the medium. Ciliata was put into the medium and cultured in the air at 25° C. 10 μl amount of the medium was sampled by a micro pipette on every time at a predetermined time interval, which was placed on a slide glass to count the number of not annihilated ciliata under a microscope.

For comparison with the example, the following Comparative Examples 2 and 3 were prepared.

### Comparative Example 2

A sprayed Ti layer identical with that in the example was formed on the metal substrate used in the example and a 2 μm polyimide coating layer was formed by a wet method. More specifically, after a hot melt adhesive type polyimide resin, which does not require a solvent, is melted by heating, the metal substrate was impregnated therewith for 5 min or more and pulled-up to solidity the polyimide resin.

### Comparative Example 3

A sprayed Ti layer identical with that in the example was formed on the metal substrate used in the example and a 2 μm epoxy coating layer was formed by a wet method. More specifically, after the metal substrate was impregnated with a two-component type epoxy resin diluted with a solvent for 5 min or more, the metal substrate was pulled-up and the epoxy resin was cured by heating.

FIG. 3 shows the results of the tests for the example and Comparative Examples 2 and 3. In FIG. 3, “initial” shows the change for the number of growth of ciliata in a medium in which the sample was not dipped. This shows that growth of ciliata was the same even when the sample of the example was immersed in the medium and the polyimide coating layer prepared by the example is not toxic. Thus, it was confirmed that the polyimide coating layer has corrosion proofness as well as biocompatibility. While the Ni—Ti substrate used for the evaluation of toxicity has a constitution of sprayed Ti layer/polyimide coating layer, it goes without saying that the sample in which the polyimide coating layer was formed directly on the Ni—Ti substrate with no sprayed Ti layer is also non-toxic.

Further, Comparative Example 2 shows the result that all ciliata were annihilated within one day after starting the evaluation test and it had no biocompatibility.

Further, Comparative Example 3 also shows the result that all ciliata were annihilated within one day after starting the evaluation test and it was found no biocompatibility was attained.

### INDUSTRIAL APPLICABILITY

The invention of this application can be applied to biomaterials since the corrosion preventing method of the invention provides shape memory alloy substrates such as of Ni—Ti-based alloys with an effect of corrosion prevention as well as biocompatibility. Further, the polyimide coat forming step of the invention, whose effect to the metal substrates having the sprayed Ti layer having pore portion has been found, has a possibility of being applicable to the purpose of corrosion prevention of metal coating layers used for MEMS (micro electro mechanical systems) constructed by a fine fabrication technique on a substrate such as of Si, and micro equipments served for intravital application, etc in biosensor circuits or micro inspection systems.

1. A corrosion preventing method for a metal substrate used for biomaterials in which a polyimide coating layer is formed on the metal substrate by vapor deposition polymerization.

2. A corrosion preventing method according to claim 1, wherein after a sprayed metal layer is formed on the surface of the metal substrate the polyimide coating layer is formed by vapor deposition polymerization.

3. A corrosion preventing method according to claim 1, wherein the metal substrate is a shape memory alloy.

4. A corrosion preventing method according to claim 2, wherein the sprayed metal layer comprises Ti.

5. A corrosion preventing method according to claim 2, wherein the metal substrate is a shape memory alloy and the sprayed metal layer comprises Ti.

6. A biomaterial characterized by being prepared by the corrosion preventing method according to claim 1.

7. A biomaterial characterized by being prepared by the corrosion preventing method according to claim 4.
